(19) United States
(12) Patent Application Publication
(10) Pub. No.: US 2012/0170771 A1
(43) Pub. Date: Jul. 5, 2012

(54) Method Of Leveling A Plurality Of Audio Signals

(76) Inventors: Leonard Tsai, Mountain View, CA (US); Robert Campesi, San Jose, CA (US); Kenneth Chan, Fremont, CA (US)

(21) Appl. No.: 13/394,141

(22) PCT Filed: Feb. 2, 2009
(86) PCT No.: PCT/US2009/032893

§ 371 Date: Mar. 3, 2012

(51) Int. Cl. H03G 3/00

(52) U.S. Cl. 381/107

(57) ABSTRACT

A system with an input amplifier to receive and amplify a first audio signal, an output amplifier to output an audio signal which includes at least one of the amplified first audio signal and a second audio signal, a controller to adjust the input amplifier to a first input amp gain and the output amplifier to a first output amp gain to provide an output signal including the first audio signal at a first output signal level. The controller is to adjust the output amplifier to a second output amp gain to provide an audio output including the second audio signal at a second output signal level and determine an output amp ratio by dividing the first output amp gain with the second output amp gain. The controller is to determine a target input amp gain by multiplying the first input amp gain by the output amp ratio and adjust the first input amp gain to the target input amp gain to provide an audio output including the first audio signal at a third output signal level.

### BACKGROUND OF THE INVENTION

1. Field of the Invention

Embodiments of the present invention generally relate to signal processing. More specifically, embodiments of the present invention relate to audio signal processing.

2. Description of the Related Art

Multi-function audio/video (“A/V”) devices are rapidly becoming the Swiss Army knife of the 21^{st} century. The use of multifunction A/V devices as television screens, gaming system displays, audio-visual entertainment system displays, and computer displays makes the utilitarian nature of the A/V display device readily apparent. The functionality of multi-function A/V devices can be further enhanced by providing one or more connection points, usually modular “industry standard” connectors on the exterior surface of the device to permit the attachment of various external, peripheral devices such as gaming systems or DVD players.

Quite frequently, however, various devices capable of providing an audio signal to the display device will transmit the audio signal at a default audio level. Frequently, when a user switches from one audio device to another audio device, the audio level will be either unacceptably high or low. The disparate audio levels can occasionally cause damage to the audio device or the hearing of an unfortunate listener.

### SUMMARY OF THE INVENTION

A method for auto-leveling a plurality of audio signals is provided. A first audio signal can be introduced to a system comprising a first audio input, a first input amplifier having a feedback controller operably connected thereto, and a first audio output. A second audio signal can be introduced to the system further comprising a second audio input and a second audio output. An output amplifier can be connected to the first and second audio outputs. The input amplifier gain can be adjusted to a first input amp gain and the output amp gain can be adjusted to a first output amp gain to provide a system output of the first audio signal at a first output signal level. The first input amp gain and the first output amp gain can be stored in a non-volatile memory disposed in, on, or about the system. The output amp gain can be adjusted to a second output amp gain to provide a system output of an amplified second audio signal at a second output signal level. An output amp ratio, equal to the first output amp gain divided by the second output amp gain, can be intermittently or continuously calculated and the result stored in the non-volatile memory. The first input amplifier gain can be adjusted using the feedback controller by amount equal to the first input amp gain multiplied by the output amp ratio, to provide a system output of the first audio signal at a third output signal level.

As used herein, an “audio signal” refers to any signal, analog or digital, containing, all or in part, audio information or data.

As used herein, an “amplifier” refers to any device, mechanical, electrical or any combination thereof, capable of changing the amplitude of a signal. The relationship of the input to the output of an amplifier, generally expressed as a function of the input frequency, is typically referred to as the “transfer function” of the amplifier, with the magnitude of the transfer function termed the “gain” of the amplifier.

As used herein, an “output signal level' refers to the audio output level of a device. Such an output signal level is frequently referred to colloquially as the “volume” of a device or appliance. The output signal level, when referring to the “volume” of a device is typically measured in Decibels (“db”). Other parameters can also be used to characterize into “output signal level” as used herein, including without limitation, the following: frequency response, total harmonic distortion (“THD”), intermodulation distortion (“IMD”), noise, crosstalk, common-mode rejection ratio, dynamic range, signal-to-noise ratio, phase distortion, group delay, phase delay, transient response, damping factor, jitter, sample rate, bit depth, sample accuracy and synchronization, linearity, or any combination thereof.

As used herein, an “operable connection”, or a connection by which entities are “operably connected”, is one in which signals, physical communications, and/or logical communications may be sent and/or received. Typically, an operable connection includes a physical interface, an electrical interface, and/or a data interface, but it is to be noted that an operable connection may include differing combinations of these or other types of connections sufficient to allow operable control. For example, two entities can be operably connected by being able to communicate signals to each other directly or through one or more intermediate entities like a processor, operating system, a logic circuit, software, or other entity. Logical and/or physical communication channels can be used to create an operable connection.

### BRIEF DESCRIPTION OF THE DRAWINGS

Advantages of one or more disclosed embodiments may become apparent upon reading the following detailed description and upon reference to the drawings in which:

FIG. 1 is a schematic depicting an illustrative system for leveling a plurality of audio signals, according to one or more embodiments described herein;

FIG. 2 is a schematic depicting an illustrative system using the system depicted in FIG. 1 for leveling a plurality of audio signals, according to one or more embodiments described herein; and

FIG. 3 is a logic flow diagram depicting an illustrative method for leveling a plurality of audio signals using the system depicted in FIG. 1, according to one or more embodiments described herein.

### DETAILED DESCRIPTION

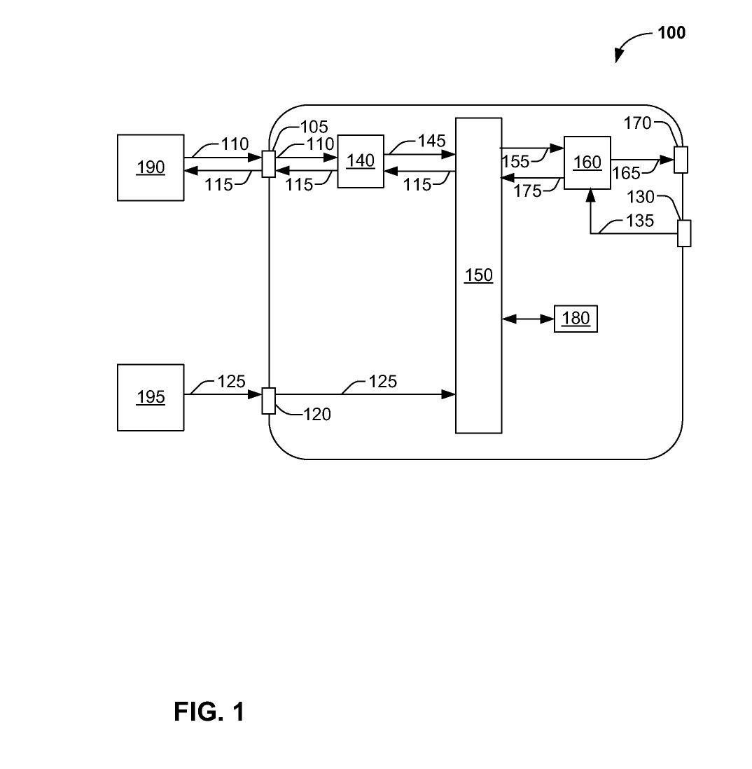

FIG. 1 is a schematic depicting an illustrative system 100 for leveling a plurality of audio signals, according to one or more embodiments. In one or more embodiments, a first audio input 105 and a second audio input 120 can be disposed in, on, or about a system 100. In one or more embodiments, the first audio input 105 can be operably connected to one or more input amplifiers (“input amps”) 140. In one or more embodiments, the one or more input amps 140 can be operably connected to a device controller 150. A first source 190 can be operably connected to the first audio input 105 to provide the first audio signal 110. In one or more embodiments, the one or more device controllers 150 can include one or more feedback controllers providing a feedback signal 115 to the first audio input 105, and to any device 190 operably connected to the first audio input 105.

In one or more embodiments, the device controller 150 can be operably connected to one or more output amplifiers (“output amps”) 160 and one or more non-volatile memory modules 180. In one or more embodiments, the one or more output amps 160 can be operably connected to one or more audio outputs 170. In one or more embodiments, the second audio input 120 can be operably connected to the device controller 150. An external device 195, for example an external audio signal generator, can be operably connected to the second audio input 120 to provide the second audio signal 125. In one or more embodiments, the one or more input amps 140, device controllers 150, output amps 160, one or more audio outputs 170, and the non-volatile memory 180 can be disposed in whole or in part, in, on, or about the system 100.

In one or more embodiments, the first audio signal 110 can be generated or otherwise transmitted from one or more first sources 190 to the one or more first audio inputs 105. The one or more first audio signals 110 can include, but are not limited to, one or more analog signals, one or more digital signals or any combination thereof. In one or more embodiments, the one or more first audio signals 110 can provide all or a portion of another signal, for example the one or more first audio signals 110 can be a portion of an audio/visual (“A/V”) signal containing both audio and video data.

The one or more first audio inputs 105 can include any connector suitable for providing one or more operable connections between the one or more input amplifiers 140 and the first source 190. In one or more embodiments, the one or more first audio inputs 105 can include one or more permanent type connectors, for example a soldered or one-way blade type connection that resists or prevents detachment. In one or more embodiments, the first audio inputs 105 can include one or more temporary or detachable connectors, for example screw type connectors, modular connectors, or blade-type connectors that permit or otherwise facilitate detachment. The one or more first audio inputs 105 can include one or more individual conduits or connectors. In one or more embodiments, the one or more first inputs 105 can comprise one or more modular connectors compliant with one or more industry standards applicable to video transmission cables or devices. Exemplary first audio inputs 105 can include, but are not limited to: one or more RCA type coaxial connectors; one or more High Definition Multimedia Interface (“HDMI”); one or more IEEE 1394 (“Firewire” or “Link”) multi-conductor connectors; or any combination thereof.

In one or more embodiments, the second audio signal 125 can be generated or otherwise transmitted from one or more second sources 195 to the one or more second audio inputs 120. The one or more second audio signals 125 can include, but are not limited to, one or more analog signals, one or more digital signals or any combination thereof. In one or more embodiments, the one or more second audio signals 125 can provide all or a portion of an audio signal, for example the one or more second audio signals 125 can be a portion of an audio/visual (“A/V”) signal containing both audio and video data.

In one or more specific embodiments, the one or more second audio signals 125 can be introduced to one or more device controllers 150 via the one or more second audio inputs 120. The second audio input 120 can include any connector suitable for providing one or more operable connections between the second source 195 and the one or more device controllers 150. In one or more embodiments, the second audio input 120 can include one or more permanent type connectors, for example a soldered or one-way blade type connection resistant to separation or detachment. In one or more embodiments, the second audio input 120 can include one or more temporary or detachable connectors, for example screw type connectors, modular connectors, or blade-type connectors that permit or otherwise facilitate detachment. The second audio input 120 can include one or more individual conduits or connectors. In one or more embodiments, the second audio input 120 can comprise one or more modular connectors compliant with one or more industry standards applicable to video transmission cables or devices. Exemplary modular second audio inputs 120 can include, but are not limited to: one or more RCA type coaxial connectors; one or more High Definition Multimedia Interface (“HDMI”); one or more IEEE 1394 (“Firewire” or “iLink”) multi-conductor connectors; or any combination thereof.

In one or more embodiments, the one or more first audio signals 110 can be introduced to one or more input amplifiers (“input amps”) 140 via one or more first audio inputs 105. The one or more input amps 140 can include, but are not limited to, one or more electrical, mechanical or electro-mechanical systems, devices, or combination of systems and/or devices suitable for amplifying the first audio signal 110 to provide an amplified first audio signal 145. In one or more embodiments, the one or more input amps 140 can include, but are not limited to, one or more transistor amplifiers. In one or more specific embodiments, the one or more input amps 140 can include, but are not limited to one or more bipolar junction transistor (“BJT”) amplifiers, one or more metal oxide semiconductor field effect transistor (“MOSFET”) amplifiers, or the like. In one or more embodiments, the one or more input amps 140 can have a single stage or multiple stages.

In one or more embodiments, one or more feedback controllers can be used to adjust the gain of the one or more input amplifiers 140. In one or more embodiments, the one or more feedback controllers can be disposed in, on, or about the device controller 150. In one or more embodiments, one or more feedback signals 115 can operatively connect the one or more feedback controllers to the one or more input amplifiers 140. In one or more embodiments, the value of the input amp gain transmitted or otherwise transferred from the device controller 150 to the one or more input amplifiers 140 via the one or more signals 115 can be stored or otherwise archived in a non-volatile memory 180 operably connected to the device controller 150. In one or more embodiments, the non-volatile memory 180 can be disposed remote from the device controller 150. In one or more embodiments, the non-volatile memory 180 can be partially or completely disposed in, on, or about the device controller 180.

While the one or more input amplifiers 140 can be disposed within the housing 185 as depicted in FIG. 1, in one or more specific embodiments, all or a portion of the one or more amplifiers 140 can be disposed in, on, or about the first source 190. In one or more embodiments, the one or more feedback signals 115 can be generated or otherwise transmitted by the device controller 150.

In one or more specific embodiments, either, or both, the amplified first audio signal 145 and/or the second signal 125 can be introduced to one or more device controllers 150. The one or more device controllers 150 can include, but is not limited to one or more systems, devices, or any combination of systems and/or devices suitable for transmission, routing, modification, enhancement, adjustment or any combination thereof, of one or more audio signals. In one or more specific embodiments, the device controller 150 can include, but is not limited to a panel controller, suitable for the transmission, generation, and/or control of one or more video signals, one or more audio signals, or one or more combined audio/visual (“A/V”) signals. In one or more specific embodiments, the one or more device controllers 150 can include, but are not limited to, one or more flat panel controllers disposed in, on, or about a computing device, for example, an all-in-one personal computer.

In one or more embodiments, one or more audio signals 155 can operatively connect the one or more device controllers 150 with one or more output amps 160. In one or more embodiments, the one or more output amps 160 can include, but are not limited to, one or more electrical, mechanical or electro-mechanical systems, devices, or combination of systems and/or devices suitable for amplifying the audio signal 155 supplied via the device controller 150 to provide a system audio output signal 165. In one or more embodiments, the one or more output amps 160 can include, but are not limited to, one or more transistor amplifiers. In one or more specific embodiments, the one or more output amps 160 can include, but are not limited to one or more bipolar junction transistor (“BJT”) amplifiers, one or more metal oxide semiconductor field effect transistor (“MOSFET”) amplifiers, or the like. In one or more embodiments, the one or more output amps 160 can include a single stage or multiple stages.

In one or more embodiments, the output amp 160 gain can be manually set, in whole or in part. In one or more specific embodiments, the output amp gain can be manually adjusted using an adjustment device 130. In one or more embodiments, the adjustment device 130 can include, but is not limited to, one or more mechanical, electrical, or electromechanical adjustment devices disposed in, on, or about the system 100. In one or more embodiments, the adjustment device 130 can include, but is not limited to, one or more remote adjustment devices operably coupled, directly or indirectly, to the gain control on the output amp 160.

Typical mechanical or electro-mechanical adjustment devices 130 can include, but are not limited to, knobs, dials, rocker switches, pushbuttons, or any combination thereof. Typical electrical, or electro-mechanical adjustment devices 130 can include, but are not limited to, electronic switches, sliders, and the like, for example, one or more interactive sliders provided by software on a computer display. In one or more embodiments, the output amp gain can be signaled, transmitted or otherwise communicated to the device controller 150 via one or more signals 175. In one or more embodiments, although not depicted in FIG. 1, the output amp gain can be signaled, transmitted or otherwise communicated to the panel controller 150, and retransmitted by the panel controller 150 to the one or more output amps 160. In one or more embodiments, the value of the output amp gain can be stored or otherwise archived in the non-volatile memory 180.

In one or more embodiments, the output signal 165 can be transmitted, transferred, or otherwise communicated via one or more audio outputs 170. In one or more embodiments, the one or more audio outputs 170 can include one or more permanent type connectors, for example a soldered or one-way blade type connection that resists or prevents detachment. In one or more embodiments, the one or more audio outputs 170 can include one or more temporary or detachable connectors, for example screw type connectors, modular connectors, or blade-type connectors that permit or otherwise facilitate detachment.

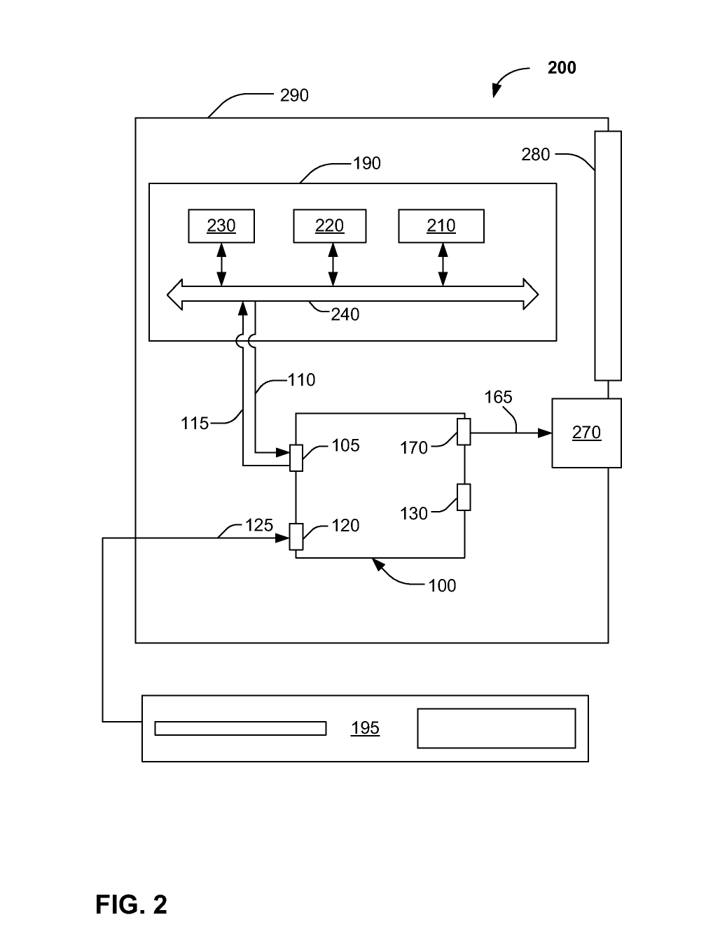

FIG. 2 is a schematic depicting an illustrative system 200 using the system 100 depicted in FIG. 1 for leveling a plurality of audio signals, according to one or more embodiments. In one or more embodiments, the audio leveling system 100 can be disposed, wholly or partially, in, on, or about a housing 290. In one or more embodiments, the first audio source 190 can also disposed wholly or partially, in, on, or about the housing 290. In one or more embodiments, the first audio source can include, but is not limited to, one or more central processing units (“CPUs”) 210, one or more memory modules 220, one or more audio processing modules 230, and one or more busses 240. In one or more embodiments, one or more video display devices 270 and one or more audio output devices 280 can be disposed in, on, or about the housing 290.

In one or more embodiments, the one or more busses can bi-directionally, operatively connect the one or more central processing units (“CPUs”) 210, one or more memory modules 220, and one or more audio processing modules 230. In one or more embodiments, all or a portion of the first audio signal 110 can be transported, transmitted, propagated, or otherwise communicated via the one or more busses 240. In one or more embodiments, all or a portion of the one or more feedback signals 115 can be communicated via the one or more busses 240.

in one or more embodiments, the one or more CPUs 210 can include one or more devices, systems, or any combination of systems and/or devices suitable for execution of one or more machine readable instruction sets. In one or more embodiments, the one or more CPUs 210 can be a dedicated device such as one of the family of Intel Pentium, Celeron, Xeon, Itaniurn microprocessors, or the like. In one or more embodiments, the one or more CPUs 210 can be a portion of a device such as a RISC based processor in a simple electronic device, or the like. In one or more embodiments, the one or more CPUs 210 can be operably connected with the one or more memory modules 220, and/or then one or more audio processing modules 230 via the one or more busses 240. In one or more embodiments, the one or more processors 210 can receive all or part of the one or more signals 115 transmitted from the first input 105 via the one or more busses 240. In one or more embodiments, the one or more CPUs 210 can include, but is not limited to, one or more 8-bit CPUs; one or more 16-bit CPUs; one or more 32-bit CPUs, one or more 64-bit CPUs, one or more 128-bit CPUs; one or more 256-bit CPUs; one or more 512-bit CPUs; one or more 1024-bit CPUs; one or more 2048-bit CPUs; or any combination thereof.

The one or more memory modules 220 can include one or more devices, systems, or any combination of systems and/or devices suitable for the temporary or permanent storage of digital data. In one or more embodiments, one or more memory modules 220 can include computer storage media in the form of volatile and/or nonvolatile memory such as read only memory (ROM) and/or random access memory (RAM). A basic input/output system (BIOS), containing the basic routines that help to transfer information between elements within the first audio source 190, for example during start-up, can be stored in ROM. RAM can contain data and/or program modules that are immediately accessible to and/or presently being operated on by the one or more CPUs 210. In one or more embodiments, the one or more memory modules 220 can receive all or part of the one or more feedback signals 115 transmitted from the first input 105 via the one or more busses 240. In one or more embodiments, the one or more memory modules 220 can be partially or wholly physically and/or electrically detachable or otherwise removable from the computing device 190.

The one or more audio processing modules 230 can include one or more devices, systems, or any combination of systems and/or devices suitable for the conversion of audio data communicated by the one or more CPUs 210 and/or the system memory 220 to provide all or a portion of the first audio signal 110. The one or more audio processing modules 230 can be combined, in whole or in part, with the one or more CPUs 210 and/or the one or more memory modules 220. In one or more embodiments, the one or more audio processing modules 230 can be a dedicated audio device, for example a sound card, disposed in, on, or about a computing device 190, such as a personal computer, a workstation, a game console, or the like.

The one or more busses 240 can include one or more devices, systems, or any combination of systems and/or devices suitable for the transmission or conveyance of digital data between one or more systems and/or devices, for example one or more CPUs 210, one or more memory modules 220, one or more audio processing modules 230, or any frequency and/or combination thereof. The one or more busses 240 can convey digital data in serial fashion or in parallel fashion. In one or more embodiments, the one or more audio processing modules 230 can transmit all or part of the first signal 110 to the first input 105 via the one or more busses 240. In one or more embodiments, the one or more audio processing modules 230 can receive all or part of the one or more feedback signals 115 transmitted from the first input 105 via the one or more busses 240. In one or more embodiments, the one or more busses can include one or more parallel busses having a width of: 8-bits or greater; 16-bits or greater; 32-bits or greater; 64-bits or greater; 128-bits or greater; 256-bits or greater; or 512-bits or greater.

The one or more audio output devices 270 can include one or more devices, systems, or any combination of systems and/or devices suitable for the conversion of an analog, digital, or any combination thereof audio signal to one or more waveforms audible to the human ear. The one or more audio output devices 270 can include, but are not limited to, one or more dynamic enclosure speakers, one or more electrostatic speakers, one or more horn-type speakers, one or more planar-magnetic speakers, one or more subwoofers, or the like, in any combination or frequency. In one or more embodiments, the one or more audio output devices 270 can be disposed partially or wholly, in, on, or about the enclosure 290.

The one or more display devices 280 can include one or more systems, devices, or any combination of systems and/or devices suitable for the display of one or more video images. The one or more display devices 280 can include, but are not limited to, one or more gas plasma display devices, one or more liquid crystal display (“LCD”) display devices, one or more light emitting diode (“LED”) display devices, one or more cathode ray tube (“CRT”) display devices, one or more organic LED (“OLEO”) display devices, one or more surface conduction electron-emitter (“SED”) display devices, or the like. The one or more display devices 280 can be disposed in whole or in part in, on, or about the housing 290. In one or more embodiments, the one or more display devices 280 can include, but are not limited to, display devices having a diagonal dimension of 5 inches (12.7 cm) or more; 8 inches (20.3 cm) or more; 12 inches (30.5 cm) or more; 19 inches (48.3 cm) or more; 24 inches (61 cm) or more; 36 inches (91,4 cm) or more; 48 inches (122 cm) or more; or 60 inches (152.4 cm) or more.

In one or more embodiments, the one or more display devices 280 can be suitable for the display of a video signal having any color space format. In one or more embodiments, the one or more display devices 280 can be suitable for the display of a video signal in a single color space format, for example a video signal in an RGB, sRGB, or xvYcc color space format. In one or more specific embodiments, the one or more display devices 280 can be suitable for the display of a video signal in a plurality of color space formats, for example a video signal having either an RGB, sRGB, or xvYcc color space format.

In one or more embodiments, the housing 290 can include any system, device, or any combination of systems and/or devices suitable for partially or completely housing all or a portion of the one or more color space matching system 100, one or more CPUs 210, one or more memory modules 220, one or more audio processing modules 230, one or more busses 240, and one or more display devices 280. In one or more embodiments, the housing 290 can include, but is not limited to, a portable computer case, a laptop computer case, a “netbook” computer case, a desktop computer case, a workstation computer case, or the like. In one or more specific embodiments, the housing can include an “all-in-one” computer case having at least the display and motherboard mounted, in whole or in part, within a single housing 290.

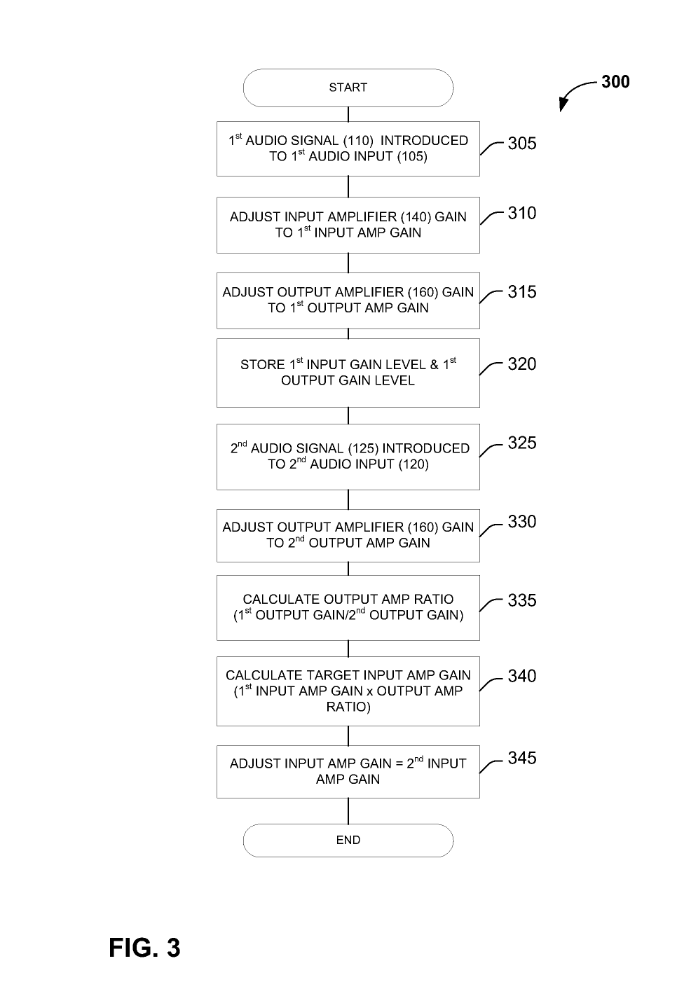

FIG. 3 is a logic flow diagram 300 depicting an illustrative method for leveling a plurality of audio signals using the system 100 depicted in FIG. 1, according to one or more embodiments. In one or more embodiments, the system can include a first audio source 190 transmitting or otherwise supplying one or more one or more first audio signals 110 to the first audio input 105 disposed in, on, or about the system 100. In one or more embodiments, the system can also include a second audio source 195 transmitting or otherwise supplying one or more second audio signals 125 to the second audio input 120.

In one or more embodiments, in step 305, the first audio signal 110, can be introduced to the first audio input 105. In one or more embodiments, all or a portion of the first audio signal 110 can be digital, analog or any combination thereof. From the first input 105, the first audio signal 110 can be introduced to the input amp 140. hi one or more embodiments, in step 310, the input amp 140 gain can be adjusted to a first input amp gain. In one or more embodiments, the input amplifier gain 140 can be adjusted using one or more electrical, mechanical, or electro-mechanical devices, for example one or more rheostats, capacitive switches, sliders, knobs, buttons, or wheels. In one or more specific embodiments, the input amp 140 gain can be adjusted using one or more software routines, for example by adjusting a volume slider control in a Microsoft® Windows® environment.

The amplified first audio signal 145 can be introduced to one or more device controllers 150. The device controller 150 can, in turn, retransmit, rebroadcast or otherwise communicate the amplified first audio signal 145, in whole or in part, as an audio signal 155. The audio signal 155 can, in turn, be introduced to the output amp 160. In one or more embodiments, in step 315, the output amp 160 gain can be adjusted to a first output amp gain. In one or more embodiments, the output amp gain can be adjusted using one or more electrical, mechanical, or electro-mechanical devices 135, for example one or more rheostats, capacitive switches, sliders, knobs, buttons, or wheels.

In one or more embodiments, in step 320, the first input amp gain and the first output amp gain can be stored in one or more memory modules, for example in the non-volatile memory 180 disposed in, on, or about the system 100, or in the one or more memory modules 220 disposed in, on, or about the first source 190. In one or more specific embodiments, the first input amp gain and the first output amp gain can be stored in a non-volatile memory 180 operatively coupled to the device controller 150. In one or more specific embodiments, the first input amp gain and the first output amp gain can be stored in a non-volatile memory 180 operatively coupled to the device controller 150 disposed in, on, or about an all-in-one computer enclosure 290.

In one or more embodiments, in step 325, the second audio signal 125 can be introduced to the second audio input 120. In one or more embodiments, all or a portion of the second audio signal 125 can be digital, analog or any combination thereof. From the second input 120, all or a portion of the second audio signal 125 can be introduced to the device controller 150. The device controller 150 can, in turn, retransmit, rebroadcast or otherwise communicate the second audio signal 125, in whole or in part, as the audio signal 155. The audio signal 155 can, in turn, be introduced to the output amp 160. In one or more embodiments, in step 330, the output amp 160 gain can be adjusted to a second output amp gain.

in one or more embodiments, in step 335, the output amp ratio defined as the first output amp gain divided by the second output amp gain, can be calculated. In one or more embodiments, the output amp ratio can be calculated, in whole or in part, using all or a portion of the device controller 150, based on the gain values stored in the non-volatile memory 180. In one or more embodiments, the output amp ratio can be calculated, in whole or in part, using all or a portion of the one or more CPUs 210, based on the gain values stored in the non-volatile memory 180 or the one or more memory modules 220.

By way of example, if the first output amp gain has a value of about 4.2 and the second output amp gain has a value of about 8.6, the output amp ratio would be equal to 4.2 divided by 8.6 or about 0.49. In one or more specific embodiments, the output amp ratio can be stored in the non-volatile memory 180. In one or more specific embodiments, the output amp ratio can be calculated intermittently on a temporal basis, for example on a time basis, e.g. once per second, every ten seconds, etc. In one or more specific embodiments, the output amp ratio can be calculated intermittently on an event driven basis, for example when a change in the second output amp gain is sensed by the device controller 150. In one or more specific embodiments, the output amp ratio can be calculated continuously.

In one or more embodiments, in step 340, the output amp ratio can be used to calculate a target input amp gain defined as the first input amp gain multiplied by the output amp ratio. By way of example, if the first input amp gain has a value of about 5.6, and the first output amp gain has a value of about 4.2, and the second output amp gain has a value of about 8.6, the output amp ratio would be equal to 4.2 divided by 8.6 or about 0.49, and the target input amp gain would be equal to (4.2 divided by 8.6) times 5.6, or about 2.7.

In one or more specific embodiments, the target input amp gain can be stored in the non-volatile memory 180. In one or more specific embodiments, the target input amp gain can be calculated intermittently on a temporal basis, for example on a time basis, e.g. once per second, every ten seconds, etc. In one or more specific embodiments, the target input amp gain can be calculated intermittently on an event driven basis, for example when a change in the second output amp gain is sensed by the device controller 150. In one or more specific embodiments, the target input amp gain can be calculated continuously.

In one or more embodiments, in step 345, the input amp gain can be adjusted by the device controller 150 using the feedback signal 115 to a level equal to the target input amp gain calculated in step 340. In one or more specific embodiments, the input amp gain can be adjusted intermittently on a temporal basis, for example on a time basis, e.g. once per second, every ten seconds, etc. In one or more specific embodiments, the input amp gain can be adjusted intermittently on an event driven basis, for example when a change in the second output amp gain is sensed by the device controller 150. In one or more specific embodiments, the input amp gain can be adjusted continuously. Since the input amp gain can be adjusted intermittently or continuously by the device controller 150 via the feedback signal 115, output audio signal level fluctuations upon awakening of the one or more CPUs 210, for example from an ACPI S3 or 34 sleep mode, can be minimized.

Certain embodiments and features have been described using a set of numerical upper limits and a set of numerical lower limits. It should be appreciated that ranges from any lower limit to any upper limit are contemplated unless otherwise indicated. Certain lower limits, upper limits and ranges appear in one or more claims below. All numerical values are “about” or “approximately” the indicated value, and take into account experimental error and variations that would be expected by a person having ordinary skill in the art.

Various terms have been defined above. To the extent a term used in a claim is not defined above, it should be given the broadest definition persons in the pertinent art have given that term as reflected in at least one printed publication or issued patent. Furthermore, all patents, test procedures, and other documents cited in this application are fully incorporated by reference to the extent such disclosure is not inconsistent with this application and for all jurisdictions in which such incorporation is permitted.

While the foregoing is directed to embodiments of the present invention, other and further embodiments of the invention may be devised without departing from the basic scope thereof, and the scope thereof is determined by the claims that follow.

1. A method for adjusting audio signal levels, comprising:
amplifying a first audio signal with an input amplifier;
outputting an audio signal with an output amplifier, wherein the audio signal includes at least one of the amplified first audio signal and a second audio signal;
adjusting the input amplifier to a first input amp gain and the output amplifier to a first output amp gain to provide an output signal including the first audio signal at a first output signal level;
adjusting the output amplifier to a second output amp gain to provide an audio output including the second audio signal at a second output signal level;
determining an output amp ratio by dividing the first output amp gain with the second output amp gain;
determining a target input amp gain by multiplying the first input amp gain by the output amp ratio; and
adjusting the first input amp gain to the target input amp gain to provide an audio output including the first audio signal at a third output signal level.

2. The method of claim 1, wherein the third output signal level the second output signal level are equal.

3. The method of claim 1, wherein the system comprises a computing device selected from the group of computing devices consisting of: a laptop computer, a portable computer, a “netbook” computer, a desktop computer, a workstation computer; and an all-in-one computer.

4. The method of claim 1, wherein the system includes a device controller comprising a flat panel controller disposed in, on, or about the system, wherein the system comprises an aft-in-one computer.

5. The method of claim 1, wherein the third output signal level and the second output signal level are different.

6. The method of claim 1, wherein the feedback controller of the system continuously adjusts the gain of the input amp when the second audio signal is output.

7. The method of claim 1, wherein the first audio signal comprises one or more signals generated by a computing device.

8. The method of claim 1, wherein the second audio signal comprises one or more audio signals generated by one or more external devices.

9. A method for adjusting audio signal levels, comprising:
introducing a first audio signal from a first device to a system comprising:
a first audio input;
an input amplifier;
a device controller having one or more feedback controllers disposed therein; wherein the feedback controller is operatively connected to the primary amplifier; and
a first audio output operatively connected to the device controller; introducing a second audio signal from a second device to the system, wherein the system further comprises:
a second audio input operatively connected to device controller; and
an output amplifier (160) operatively connected to the device controller;
adjusting the input amplifier to a first input amp gain and the output amplifier to a first output amp gain to provide a first output comprising the first audio signal at a first output signal level;
storing the first input amp gain and the first output amp gain in a non-volatile memory disposed in, on, or about the system;
adjusting the output amplifier to a second output amp gain to provide a second output comprising the second audio signal at a second output signal level;
calculating an output amp ratio, wherein the output amp ratio is determined by dividing the first output amp gain by the second output amp gain;
calculating a target input amp gain, wherein the target input amp gain is determined by multiplying the first input amp gain by the output amp ratio and
adjusting, using the feedback controller, the first input amp gain to the target input amp gain to provide a third output comprising the first audio signal at a third output signal level.

10. The method of claim 9, further comprising:
operably connecting the third output to an audio output device disposed in, on, or about the first device, wherein the first device comprises:
one or more central processing units;
one or more memory modules; and
one or more audio processing units.

11. The method of claim 10, wherein the first device further comprises one or more video display devices, and wherein the controller comprises a panel controller operatively connected to the one or more video display devices.

12. The method of claim 9, wherein the output amp ratio is intermittently calculated and the target input amp gain is intermittently updated when the second audio signal is output.

13. The method of claim 9, wherein the output amp ratio is continuously calculated and the target input amp gain is continuously updated when the second audio signal is output.

14. The method of claim 10, wherein adjusting the output amplifier comprises manually adjusting the output amplifier gain using a mechanical or electrical adjustment device accessible to the user; wherein the mechanical or electrical adjustment device is disposed in, on, or about the first device.

15. A system for adjusting audio signal levels, comprising:
an input amplifier to receive and amplify a first audio signal;
an output amplifier to output an audio signal which includes at least one of the amplified first audio signal and a second audio signal;
a controller to adjust the input amplifier to a first input amp gain and the output amplifier to a first output amp gain to provide an output signal including the first audio signal at a first output signal level;
wherein the controller is additionally to adjust the output amplifier to a second output amp gain to provide an audio output including the second audio signal at a second output signal level;
wherein the controller is to determine an output amp ratio by dividing the first output amp gain with the second output amp gain;
wherein the controller is to determine a target input amp gain by multiplying the first input amp gain by the output amp ratio; and
wherein the controller is to adjust the first input amp pain to the target input amp pain to provide an audio output including the first audio signal at a third output signal level.
